(19) United States
(12) Patent Application Publication
(10) Pub. No.: US 2005/0183843 A1
(43) Pub. Date: Aug. 25, 2005

(54) Heat sink

(75) Inventors: Masataka Mochizuki, Tokyo (JP); Koichi Mashiko, Patumthani (TH); Thang Nguyen, Rowville (AU); Pakawat Visudthimark, Patumthani (TH); Vijit Wuttijumnong, Santa Clara, CA (US)

Correspondence Address: SUGHRUE MION, PLLC, 2100 PENNSYLVANIA AVENUE, N.W., SUITE 800, WASHINGTON, DC, 20037, US

(73) Assignee: FUJIKURA LTD.

(21) Appl. No.: 11/055,678

(22) Filed: Feb. 11, 2005

Related U.S. Application Data
(60) Provisional application No. 60/543,906, filed on Feb. 13, 2004.

(51) Int. Cl. H05K 7/20

(52) U.S. Cl. 165/80.3; 361/697; 165/121

(57) ABSTRACT

A heat sink, which comprises a plurality of flat fins erected on a surface of a base portion, and an air passage defined by the flat fins. In the heat think, at least one of the side end portions of one of the flat fins protrudes outwardly from a peripheral edge of the base portion.

This application claims priority from Provisional Application Ser. No. 60/543,906, filed Feb. 13, 2004, pending, incorporated herein by reference.

### BACKGROUND OF THE INVENTION

1. Field of the Invention

The present invention deals with a heat sink comprising a plurality of flat fins erected on a surface of a base portion.

2. Discussion of the Related Art

Generally, a heat sink is contacted with an exothermic member or a heat source to enlarge the substantial heat radiation area of the exothermic member or the heat source. For this reason, it is preferable to arrange the fins or the heat radiation faces as many as possible in the heat sink of this kind. However, in order to secure the applicability to any kind of cooling objects having various shapes, heat sink having the heat radiation fins on its base portion is used generally. In the prior art, there is known a heat sink, in which flat heat radiation fins are erected integrally on one of a surface of a base portion in a parallel manner.

The heat sink of this kind has a large heat radiation area in total so that large quantity of heat can be radiated. However, in order to further enhance the heat radiation capacity, it is preferable to carry out a compulsory cooling by blowing air. In this case, the cooling air is flown through a clearance between radiation fins to facilitate heat radiation from the surface of each radiation fins. In consideration of the heat radiation efficiency and the flexibility of installation, for example, an air blowing means such as a fan may be arranged above the radiation fins, in other words, on the opposite side of the base portion.

In the above mentioned heat sink, the heat transmitted to the base portion is further transmitted to the flat fins while sending the cooling air into the clearance between the fins by the air blowing means such as a fan, therefore, the heat of the heat radiation fin is carried away by the cooling air. As a result of this, an exothermic member being contacted to the base member is cooled by the cooling air indirectly. In this case, the substantial heat radiation area of the exothermic member is enlarged by the fins. Moreover, heat transfer rate between the fin and the cooling air contacting thereto can be raised by widening temperature difference between those; therefore, the heat can be radiated efficiently and temperature raise in the exothermic member is prevented or suppressed. One example of the heat sink having this kind of structure is disclosed in Japanese Patent Laid-Open No. 2001-319998.

In the heat sink thus far described, the heat radiation area can be enlarged by increasing the number of the fins. However, if the base portion is relatively large compared to the cooling object, i.e., to the exothermic member, the thermal resistance of the base portion is increased so that the heat radiation efficiency (i.e., cooling performance) is degraded. Moreover, the heat sink is desirable to be reduced in its size and weight, so that flow paths of the cooling air are narrowed if the number of the fins is increased. For this reason, it is difficult for the air flow to get into the clearance between the fins even if the compulsory cooling is carried out. Furthermore, flow of the cooling air is hindered. Due to those factors, the heat radiating effect of the heat sink may be deteriorated. In other words, the substantial heat radiation area will not be enlarged even if the number of the fins is increased. Therefore, the heat radiating performance of the heat sink is limited.

### SUMMARY OF THE INVENTION

The present invention has been conceived in view of the aforementioned technical problems, and it is an object of the present invention to improve heat radiating characteristics of a heat sink comprising a plurality of flat fins.

An exemplary heat sink according to the present invention comprises a plurality of flat fins erected on a surface of a base portion, and clearances between those fins function as air passages. In the heat sink of the invention, at least one of the side end portions of at least one of the flat fins protrudes outwardly from a peripheral edge of the base portion.

In the heat sink of the invention, an air passage is formed between a pair of adjoining flat fins, and at least one of the side end portions thereof protrudes outwardly from the peripheral edge of the base portion. Consequently, the lower end portion of the air passage protruding from the base portion functions as a flow outlet.

According to the invention, therefore, both top and bottom portions of the air passage being defined by the flat fins are opened. In other words, the air passage is opened on the base portion side and the upper side. For this reason, in case of arranging an air blowing means above the base portion and fins and sending cooling air into the air passage, the airflow vertical to the base portion is discharged from the lower end of the air passage. As a result, airflow resistance in the air passage is reduced and the flow of the cooling air is thereby facilitated. This improves the heat radiating characteristics of the heat sink entirely.

According to the invention, moreover, there is provided a heat sink, which has: a plurality of flat fins erected on the surface of the base portion; air passages being defined by the flat fins, and an air blowing means for establishing airflow toward the base portion, which is arranged above the flat fins. This heat sink is characterized by comprising an exhaust slot portion for discharging the airflow established by the air blowing means and flowing through the air passage toward the base portion.

The exhaust slot portion includes a lower end opening of the air passage protruding from the base portion. As mentioned above, the air passage is defined by the flat fins, and at least one of the side end portions thereof protrudes outwardly from the peripheral edge of the base portion.

The exhaust slot portion may also be a through hole portion penetrating the base portion from top to bottom.

According to the invention, therefore, the airflow established by the air blowing means flows through the air passage to the base portion, and then flows through the base portion from top to bottom. For this reason, the flow of the air is smoothened in the air passage. Consequently, the heat radiating characteristics of the heat sink is improved entirely.

The exemplary heat sink according to the present invention further comprises a pedestal portion, which is arranged on the surface of the base portion opposite to the surface where the flat fins are erected. The pedestal portion has heat conductivity higher than that of the base portion, and an exothermic member is contacted thereto in a heat transmittable manner.

According to the invention, therefore, the heat generated by the exothermic member is transferred to the base portion through the pedestal portion. This facilitates thermal diffusion and heat transfer from the exothermic member to the base portion. Consequently, a thermal resistance of the heat transfer route from the exothermic member to the flat fins is reduced, and the heat radiating characteristics of the heat sink is thereby improved entirely.

The above and further objects and novel features of the invention will more fully appear from the following detailed description when the same is read with reference to the accompanying drawings. It is to be expressly understood, however, that the drawings are for purpose of illustration only and are not intended as a definition of the limits of the invention.

### BRIEF DESCRIPTION OF THE DRAWINGS

FIG. 1 is a front view showing one example of a heat sink according to the invention.

FIG. 2 is a side view showing the heat sink shown in FIG. 1.

FIG. 3 is an enlarged view showing exhaust slots of the heat sink shown in FIG. 1.

FIG. 4 is a perspective view showing another example of a heat sink according to the invention.

FIG. 5 is a perspective view showing the heat sink shown in FIG. 4 from different angle.

FIG. 6 is a side view showing the heat sink shown in FIG. 4.

### DETAILED DESCRIPTION OF THE INVENTION

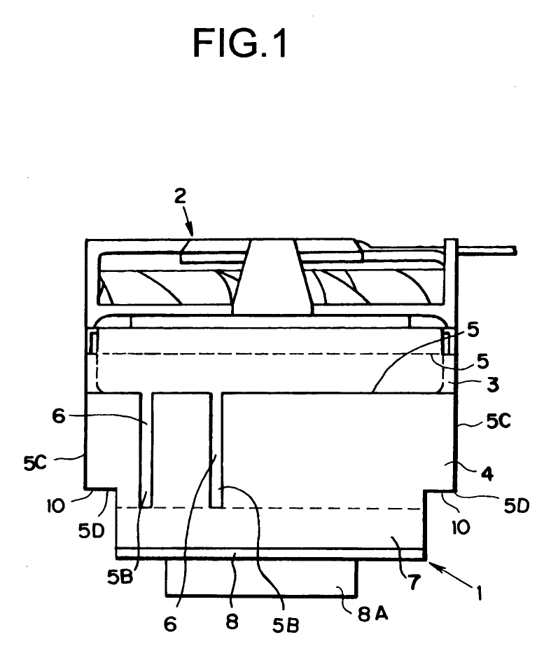

Here will be described the exemplary embodiment of the invention. FIG. 1 shows one example of a heat sink according to the invention. The construction of the heat sink 1 will be described first of all. The heat sink 1 comprises a flat fin 3, an external wall 4 having a function as a radiation fin, a base portion 7 and a heat spreader 8. The flat fin 3, the external wall 4 and the base portion 7 are formed integrally of aluminum or aluminum alloy, for example. On the other hand, the heat spreader 8 is made of copper.

The flat fin 3 and the external wall 4 are elected on the surface of the base portion 7 at a regular interval in a parallel manner. The longitudinal lengths of the flat fin 3 and the external wall 4 are longer than that of the base portion 7.

Here will be described the arrangement of the flat fins 3 and the external walls 4. A plurality of the flat fins 3 is arranged at the regular interval in parallel manner on the surface of the base portion 7, and the external walls 4 are arranged on both outer ends. In other words, the flat fins 3 are sandwiched between two external walls 4 in the arranging direction. Consequently, an air passage 5 is formed linearly in each clearance between flat fins 3, and between the flat fin 3 and the external wall 4. Airflow is to be flown through each air passage 5. Additionally, both end portions of the air passage 5 in the longitudinal direction are flow outlets 5C.

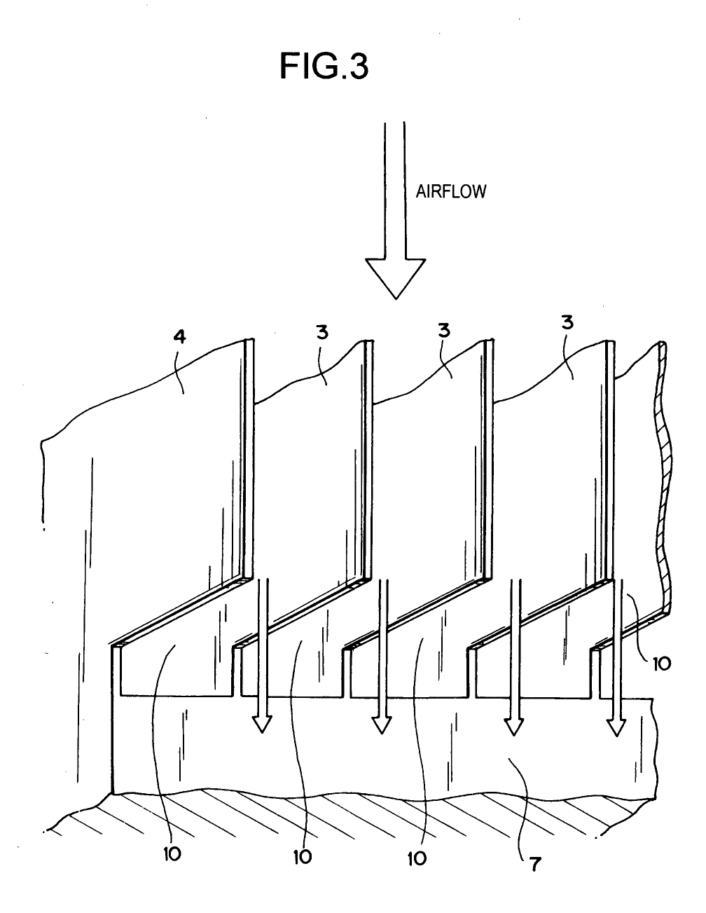

As shown in FIG. 3, an exhaust slot 10 is composed of the side end portions of the flat fins 3, or composed of side end portions of the flat fin 3 and the external wall 4. Specifically, the exhaust slot 10 is composed of the side end portions of the flat fin 3 and the external wall 4 protruding from the base portion 7. The exhaust slots 10 are formed on both side ends of the fin 3 and the external wall 4. Accordingly, the lower end portion of the exhaust slot 10 is a flow outlet 5D opening in the thickness direction of the base portion 7 (i.e., the vertical direction).

An axial-flow fan 2 facing the base portion 7 (i.e. facing downwardly) is arranged above the flat fins 3 and the external wall 4. Accordingly, a clearance between the upper end portions of the flat fins 3, and a clearance between the fin 3 and the external wall 4, are flow inlets 5A of the air passage 5 and a slit 6.

A plurality of the slits 6 is formed in the flat fins 3 as well as in the external wall 4, at the predetermined positions in the longitudinal direction. The slit 6 is formed from the upper end of the flat fin 3 and the external wall 4 to the vicinity of the surface of the base portion 7. Additionally, the position of each slit 6 is deviated away from one another little by little. As a result, a plurality of flow passages is formed so as to cross the air passage 5 diagonally. Therefore, the slit 6 of the external wall 4 is a flow outlet 5B for discharging the airflow.

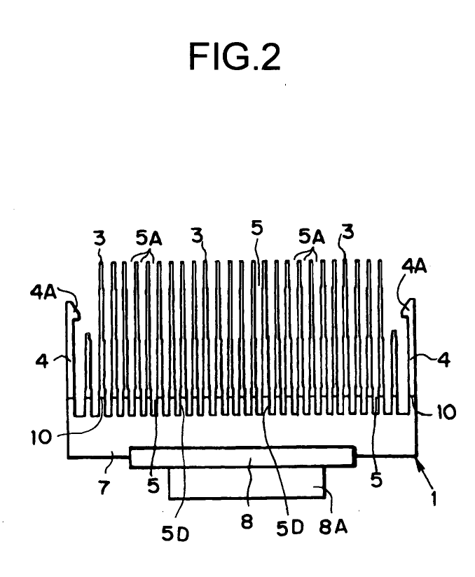

As shown in FIG. 2, the external wall 4 is provided with a hook portion 4A on its leading end opposite to the base portion 7. Here, the axial-flow fan 2 is eliminated from FIG. 2. This hook portion 4A is coupled with the peripheral edge of a housing of the axial-flow fan 2. As a result, the axial-flow fan 2 is joined integrally with the heat sink 1. In Addition, a height of the flat fin 3 next to the external wall 4 is shorter than that of the other flat fins 3, so as not to interfere with the peripheral edge of the axial-flow fan 2 when the axial-flow fan 2 is joined with the heat sink 1.

An exothermic member 8A is attached to the heat spreader 8 in a heat transferable manner. The heat spreader 8 is shaped rectangular, and fitted into a recess portion 7A formed on the bottom of the base portion 7. The recess portion 7A and the heat spreader 8 are fixed by soldering.

Here will be described the action of the heat sink 1. As described above, the air passage 5 is formed between the flat fins 3, or between the flat fin 3 and the external wall 4. Moreover, both top and bottom ends of the protruding portion of the air passage 5 are opened to form the exhaust slot 10. Therefore, the cooling air in the air passage 5 sent by the axial-flow fan 2 is then flown through the exhaust slot 10. Since the exhaust slot 10 is formed vertically with respect to the axial-flow fan 2, the flow resistance is reduced in the air passage 5 and the flowage of the cooling air is thereby facilitated. Consequently, the heat radiating characteristics of the heat sink 1 is improved entirely.

Moreover, the heat generated at the exothermic member 8A is transmitted to the base portion 7 through the heat spreader 8, so that the heat transfer and the heat radiation between the exothermic member 8A and the base portion 7 are facilitated. As a result, a thermal resistance of the heat transfer route from the exothermic member 8A to the flat fin 3 or to the external wall 4 is reduced, and the heat radiating characteristics of the heat sink 1 is thereby improved entirely.

Furthermore, flow outlets 5B and 5D are formed on both end portions of the flat fin 3, in addition to the flow outlet 5C. Therefore, the discharge amount of the cooling air flowing through the air passage 5 is increased.

According to the aforementioned heat sink 1, both side ends of the air passage 5 being defined by the fins 3 and protruding from the base portion 7 are the flow outlets 5C. Consequently, the heat radiating area of the heat sink 1 is thereby enlarged with respect to the dimensions of the base portion 12. Therefore, it is possible to improve the heat radiation efficiency of the heat sink 1.

On the other hand, the axial-flow fan 2 can be fixed easily to the heat sink 1 by means of the hook portion 4A of the external wall 4. This allows a body portion of the conventional heat sink to function as the external wall 4. As a result, the heat radiating area of the heat sink 1 can be enlarged and the heat radiating capacity of the heat sink 1 is therefore improved. Moreover, the number of parts can be reduced to lower the manufacturing cost.

The airflow is also discharged from the flow outlet 5B formed in the slit 6. This increases the flow amount of the cooling air passing through the air passage 5, so that the heat exchange efficiency is improved. For this reason, the cooling performance of the heat sink 1 is enhanced.

Since the heat spreader 8 is fitted into the recess portion 7A formed on the bottom of the base portion 7, moreover, the contacting dimensions between the base portion 7 and the heat spreader 8 can be enlarged. Consequently, the heat transferred to the heat spreader 8 can be efficiently transmitted to the base portion 7, and the cooling performance of the heart sink 1 is thereby improved.

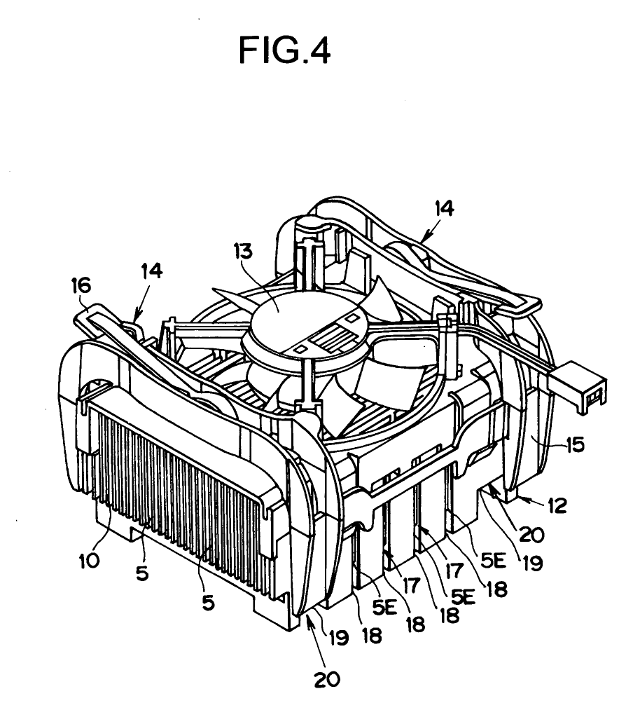

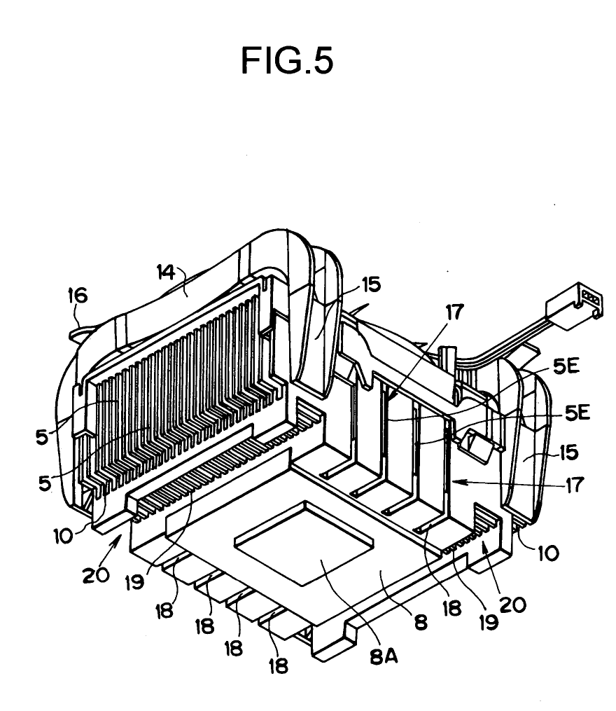

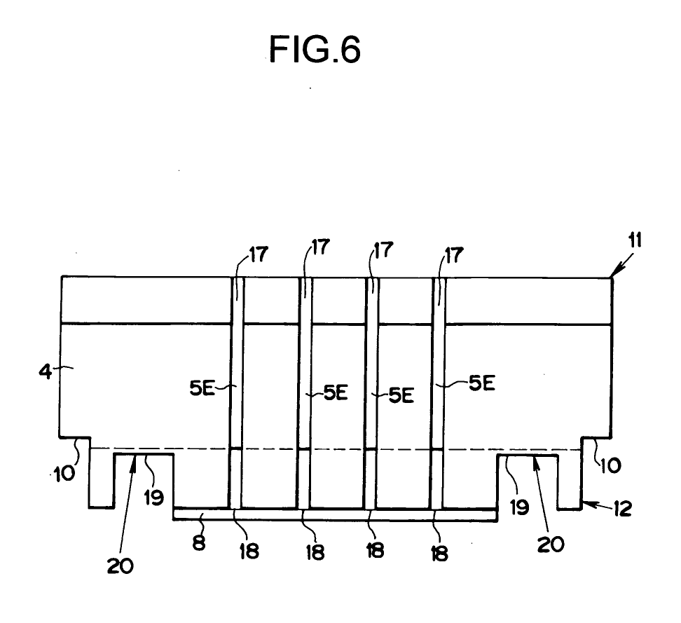

Here will be described another specific embodiment according to the invention. Here, further description of the constructions identical or similar to those of the foregoing specific embodiment will be omitted by allotting common reference numerals. In FIGS. 4 to 6, there is shown a heat sink 11 as another specific embodiment of the invention. The heat sink 11 comprises the flat fins 3, the external wall 4, the base portion 12 and the heat spreader 8 made of copper. In the heat sink 11, the flat fin 3, the external wall 4 and the base portion 12 are made of aluminum or aluminum alloy, and those are formed integrally by, e.g., the die-casting process. Moreover, both side end portions of the flat fins 3 and the external wall 4 function as the exhaust slots 10. Accordingly, the lower end of the exhaust slots 10 composed of the flat fins 3 or of the flat fin 3 and the external wall 4 is the flow outlet 5D.

An axial-flow fan 13 is arranged above the external wall 4. The axial-flow fan 13 is fixed with the base portion 12 by a pair of clips 14. Specifically, each clip 14 has bent arm portions 15, and the base portion 12 and the axial-flow fan 13 are clamped integrally between the end portions of the arm portions 15. Moreover, the arm portion 15 is equipped with a fastening tool 16 for tightening the arm portions 15. The base portion 12 and the axial-flow fan 13 are clamped by adjusting the fastening tool 16.

Moreover, there are formed slits 17 vertically from the top end of the external wall 4 to the bottom end of the base portion 12. Consequently, there are formed openings on the bottom face of the base portion 12 underneath the slits 17. Those openings function as exhaust slots 18 for discharging the cooling air from the air passage 5 being defined by the flat fins 3. Moreover, the slit 17 penetrates the several flat fins 3 from the external wall 4. This allows the cooling air in the air passage 5 to be discharged from the openings of the external wall 4. Namely, the openings of the external wall 4 are flow outlets 5E for discharging the cooling air.

Furthermore, there are formed through holes 19 penetrating the base portion 12 in the thickness direction. Accordingly, the cooling air in the air passage 5 being defined by the flat fins 3 can also be discharged from the through hole 19 of the base portion 12. Namely, the through hole 19 of the bottom face of the base portion 12 functions as an exhaust slot 20 for discharging the cooling air.

Next, the action of the heat sink 11 will be explained hereinafter. When the cooling air is sent to the air passage 5 by the axial-flow fan 13 arranged above the fins 3 and the external walls 4, the cooling air is flown into the slit 17 and the through hole 19. For this reason, the cooling air is discharged not only from the exhaust slot 10 but also from the exhaust slots 18 and 20. As a result, the flow of the cooling air is smoothened in the heat sink 11 so that the flow amount of the cooling air in the heat sink 11 is increased. Specifically, the heat sink 11 comprises not only the exhaust slot 10 positioned at both side ends of the flat fin 3, but also the exhaust slot 18 or the slit 17 and the exhaust slot 20 or the through hole 19. Moreover, those exhaust slots are opposed to the axial-flow fan 13. According to the heat sink 11, therefore, the flowability of the cooling air in the air passage 5, and the heat radiating characteristics or the cooling performance of the heat sink 11 itself are improved, in addition to the action of achieved by the heat sink 1 shown in FIGS. 1 to 3.

Here will be briefly described the corresponding relation between the aforementioned embodiments and the invention. The heat spreader 8 corresponds to a pedestal portion of the invention; the slit 17 and the through hole 19 correspond to a through hole portion of the invention; and the slit 17 corresponds to a slit portion.

Here, in the aforementioned embodiment, the flat fins and the base portion are made of aluminum or aluminum alloy, and the heat spreader is made of cooper. However, the materials of the flat fin, the base portion and the heat spreader are not limited to aluminum, aluminum alloy or copper. For example, the base portion may be made of copper, and the heat spreader may be made of aluminum. Otherwise, the base portion and the heat spreader may be made of same material.

Here will be synthetically described the advantages to be attained by the invention. According to the invention, both top and bottom portions of the air passage being defined by the flat fins are opened; therefore, the airflow vertical to the base portion is partially discharged from the lower opening end of the air passage. As a result, the flow resistance is reduced in the air passage so that the flowage of the cooling air is facilitated. The heat radiating characteristics of the heat sink is thereby improved entirely.

According to the invention, moreover, the airflow established by the air blowing means and flowing toward the base portion through the air passage is discharged from the exhaust slot. Therefore, the airflow in the air passage is smoothened so that the heat radiating characteristics of the heat sink can be improved entirely.

According to the invention, furthermore, the heat generated at the exothermic member is transferred to the base portion through the pedestal portion, thereby facilitating thermal diffusion and the heat transfer from the exothermic member to the base portion. As a result, the heat resistance of the heat transfer route from the exothermic member to the flat fin is reduced. Therefore, the heat radiating characteristics of the heat sink is improved entirely.

1. A heat sink, comprising:
a plurality of flat fins erected on a surface of a base portion;
an air passage defined by the flat fins; and
wherein at least one of the side end portion of at least one of the flat fins protrudes outwardly from an outer peripheral edge of the base portion.

2. The heat sink according to claim 1, further comprising:
a pedestal portion, which is arranged on a surface of the base portion opposite to the surface where the flat fins are erected, which has heat conductivity higher than that of the base portion, and to which an exothermic member is contacted in a heat transmittable manner.

3. The heat sink according to claim 2, further comprising:
a flow outlet, which is formed in the lower end portion of the air passage defined by a pair of adjoining flat fins in which at least one of the side end portions thereof protrudes outwardly from the peripheral edge of the base portion.

4. The heat sink according to claim 3, comprising:
a pedestal portion, which is arranged on a surface of the base portion opposite to the surface where the flat fins are erected, which has heat conductivity higher than that of the base portion, and to which an exothermic member is contacted in a heat transmittable manner.

5. A heat sink, comprising:
a plurality of flat fins erected on the surface of the base portion;
an air passage defined by the flat fins;
an air blowing means for establishing an airflow in the direction of the base portion, which is arranged above the flat fins and being faced to the base portion; and
an exhaust slot portion for letting through the airflow which is established by the air blowing means and which flows through the air passage to the base portion, from top to bottom of the base portion.

6. The heat sink according to claim 5, wherein:
the exhaust slot portion includes a through hole portion penetrating the base portion from top to bottom.

7. The heat sink according to claim 5, comprising:
a pedestal portion, which is arranged on a surface of the base portion opposite to the surface where the flat fins are erected, which has heat conductivity higher than that of the base portion, and to which an exothermic member is contacted in a heat transmittable manner.

8. The heat sink according to claim 5, wherein:
the exhaust slot portion includes the lower end opening of the air passage, which is defined by the flat fins in which at least one of the side end portions protrudes outwardly from the peripheral edge of the base portion.

9. The heat sink according to claim 8, wherein:
the exhaust slot portion includes a through hole portion penetrating the base portion from top to bottom.

10. The heat sink according to claim 8, comprising:
a pedestal portion, which is arranged on a surface of the base portion opposite to the surface where the flat fins are erected, which has heat conductivity higher than that of the base portion, and to which an exothermic member is contacted in a heat transmittable manner.
